(19) United States
(12) Patent Application Publication
(10) Pub. No.: US 2010/0126289 A1
(43) Pub. Date: May 27, 2010

(54) METHOD OF MOUNTING CONTACTOR

(75) Inventor: Seizo Kinoshita, Tokyo (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 12/532,893

(22) PCT Filed: Mar. 18, 2008
(86) PCT No.: PCT/JP2008/054993

§ 371 Date: Sep. 24, 2009

(30) Foreign Application Priority Data
Apr. 3, 2007 (JP) 2007-097261

(51) Int. Cl. G01R 1/073; H05K 3/30

(52) U.S. Cl. 73/866.5; 29/833

(57) ABSTRACT

A method of mounting a contactor comprising: a step S10 of recognizing a reference point on a mount base; a step S12 of recognizing the positions of first marks on the mount base to calculate the actual relative position m₁ of the first marks with respect to the reference point; a step S13 of calculating a theoretical relative position m₀ in design of the first marks with respect to the reference point; a step S14 of calculating the relative amount of deviation Δm of the actual relative position m₁ with respect to the theoretical relative position m₀; a step S22 of recognizing the positions of first marks in the mounting system; a step S23 of specifying the mounting position of the contactor on the mount base on the basis of the amount of deviation Δm and the position of the first marks; and steps S27 and S28 of mounting the contactor at the mounting position.

### TECHNICAL FIELD

The present invention relates to a method of mounting a contactor on a probe board, the contactor is for electrical connection with an input/output terminal of a semiconductor integrated circuit device or other electronic device (hereinafter also referred to as representatively as an “IC device”) in a probe card establishing electrical connection between an IC device when testing an IC device.

### BACKGROUND ART

A large number of semiconductor integrated circuit devices are built into a silicon wafer or other semiconductor wafer, then are diced, bonded, packaged, and otherwise processed to form finished electronic devices. Such IC devices are subjected to operational tests before shipment. These IC tests are run in the state of the finished products and in the state of the wafer.

As the probe needles for establishing electrical connection with an IC device when testing the IC device in the wafer state, ones made at a semiconductor wafer using photolithography or other semiconductor production technology (hereinafter also referred to simply as “silicon finger contactors”) have been known in the past (for example, see Patent Literature 1). Each silicon finger contactor comprises: a base part attached to a probe board; beam parts with rear end sides provided at the base part and with front end sides sticking out from the base part in finger shapes (comb shape); and conductive parts formed on the surfaces of the beam parts and electrically connecting with input/output terminals of an IC device.

When using such silicon finger contactor to produce a probe card, the probe board is coated with an adhesive at predetermined position, the base part of the silicon finger contactor is positioned at the coated position, and the adhesive is cured to mount the silicon finger contactor on the board.

This series of mounting steps is performed using a dedicated mounting system. Image processing technology etc. is used to position each silicon finger contactor 60 on the board 51. Specifically, as shown in FIG. 8, first the positions of first marks 51d actually provided on the board 51 and the positions of second marks 61b provided on the silicon finger contactor 60 are recognized, a midpoint M₁ is calculated from the positions of the first marks 51d, and a midpoint M₂ is calculated from the positions of the second marks 61b. Next, the silicon finger contactor 60 is positioned on the board 51 so that the midpoint M₂ of the marks 61b of the contactor 60 is positioned a predetermined distance L away from the midpoint M₁ of the first marks 51d.

A large number of silicon finger contactors 60 are mounted on the board 51 by the above procedure, but as shown in FIG. 8, the processing tolerance of the first marks 51d is about ±10 μm or so, so there is a maximum 20 μm or so variation between adjoining first marks 51d. On the other hand, the input/output terminals at the wafer under test side have a narrow pitch of several tens to several hundreds of μm, so there is a good possibility of missed contact between the contactors 60 and the input/output terminals on the wafer under test at the time of testing an IC device.

As factors influencing the mounting precision, in addition to the processing precision of the first marks on the board, the error in recognition of the marks, operating precision, etc. of the mounting system may be mentioned, but these precisions can be made within ±several μm, so the processing precision of the first marks has the greatest effect on the mounting precision.

Further, along with the greater size of the boards on which the silicon finger contactors are mounted and the greater number of silicon finger contactors mounted, the processing error of the first marks cumulates, so the effect of the processing precision of the first marks on the mounting precision tends to be larger.
Patent Literature 1: Japanese Patent Publication (A) No. 2000-249722
Patent Literature 2: Japanese Patent Publication (A) No. 2001-159642
Patent Literature 3: International Publication No. 03/071289 pamphlet

### SUMMARY OF INVENTION

### Technical Problem

The problem to be solved by the present invention is to provide a method of mounting a contactor able to mount a contactor on a board with a high precision.

### Solution to Problem

To achieve the above object, according to the present invention, there is provided a method of mounting a contactor on a board, the contactor for electrical contact with input/output terminal of a device under test at the time of testing the device under test, the method of mounting a contactor comprising: a first recognition step of recognizing a position of a reference point provided on the board; a first calculation step of recognizing a position of a first mark provided on the board for showing a position for mounting the contactor and calculating an actual relative position of the first mark with respect to the reference point; a second calculation step of calculating a theoretical relative position in design of the first mark with respect to the reference point; a third calculation step of calculating a relative amount of deviation of the actual relative position with respect to the theoretical relative position on the basis of the actual relative position calculated in the first calculation step and the theoretical relative position calculated in the second calculation step; a second recognition step of recognizing the positions of the first mark; a specifying step of specifying a mounting position of the contactor on the board on the basis of the amount of deviation calculated in the third calculation step and the position of the first mark recognized in the second recognition step; and a mounting step of mounting the contactor at the position specified in the specifying step.

While not particularly limited in the invention, preferably the specifying step comprises: calculating the theoretical position in design of the first mark on the basis of the position of the first mark recognized in the second recognition step and the amount of deviation calculated in the third calculation step; and specifying the theoretical position as the mounting position of the contactor on the board.

While not particularly limited in the invention, preferably the method further comprises a third recognition step of recognizing a position of a second mark provided on the contactor for recognizing the position of the contactor, wherein the mounting step comprises mounting the contactor on the board so that the second mark is positioned at the mounting position or the second mark is positioned a predetermined distance away from the mounting position.

While not particularly limited in the invention, preferably the first recognition step and the first calculation step respectively comprise recognizing the position of the reference point and the positions of the first mark by a first measurement system, and the second recognition step and the third recognition step respectively comprise recognizing the position of the first mark and the position of the second mark by a second measurement system different from the first measurement system.

While not particularly limited in the invention, preferably, when mounting a plurality of the contactors on the same board, the respective first recognition steps comprise recognizing the position of the same reference point.

While not particularly limited in the invention, preferably the method further comprises a coating step of coating an adhesive on the mounting position specified in the specifying step.

While not particularly limited in the invention, preferably the contactor has a base part fixed to the board, beam parts with rear end sides provided at the base part and front end sides sticking out from the base part, and conductive parts formed on surfaces of the beam parts and electrically connecting with input/output terminals of the device under test, one the base part is provided with a plurality of the beam parts, and the second mark is provided at the base part.

### ADVANTAGEOUS EFFECTS OF INVENTION

In the present invention, a reference point at a board is provided, a relative position of an actual first mark (actual relative position) and relative position of a first mark in the design (theoretical relative position) with respect to the reference point are calculated, the relative amount of deviation of the actual relative position with respect to the theoretical relative position is calculated, and this amount of deviation is considered when specifying the mounting position of the contactor on the board. Due to this, it is possible to cancel out the processing error occurring when providing the first mark on the board, so it is possible to accurately mount the contactor on the board.

### BRIEF DESCRIPTION OF DRAWINGS

FIG. 1 is a schematic cross-sectional view of an electronic device test system in an embodiment of the present invention.

FIG. 2 is a cross-sectional view showing a probe card in an embodiment of the present invention.

FIG. 3 is a bottom view showing a probe card in an embodiment of the present invention.

FIG. 4 is a cross-sectional view showing a silicon finger contactor in an embodiment of the present invention.

FIG. 5 is a plan view showing a silicon finger contactor in an embodiment of the present invention.

FIG. 6 is a flow chart showing a method of mounting a contactor in an embodiment of the present invention.

FIG. 7A is a partial plan view of a mount base for explaining steps S11 to S14 in FIG. 6.

FIG. 7B is a partial plan view of a mount base for explaining steps S22 to S27 in FIG. 6.

FIG. 7C is a side view showing step S24 in FIG. 6.

FIG. 7D is a side view showing step S27 in FIG. 6.

FIG. 7E is a side view showing step S28 in FIG. 6.

FIG. 8 is a plan view showing a conventional method of mounting a contactor.

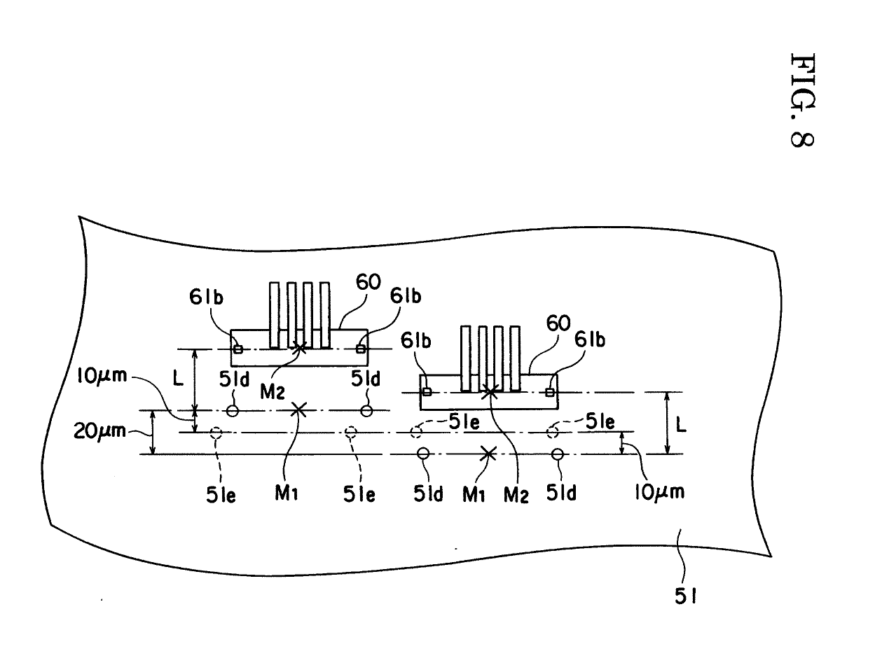

### REFERENCE SIGNS LIST

1 . . . electronic device test system
10 . . . test head
50 . . . probe card
51 . . . mount base
51c . . . reference point
51d . . . first mark
M₁ . . . midpoint
51e . . . first mark in design
M₀ . . . midpoint
51f . . . mounting position
52 . . . bonding wire
53 . . . support column
54 . . . limiter
55 . . . circuit board
56 . . . base member
57 . . . stiffener
60 . . . probe needle
61 . . . base part
61b . . . second mark
M₂ . . . midpoint
62 . . . beam part
63 . . . conductive layer
80 . . . prober
W . . . semiconductor wafer
Δm . . . amount of deviation

### EMBODIMENTS OF INVENTION

Below, an embodiment of the present invention will be explained based on the drawings.

First, the configuration of an electronic device test system comprising a probe card to which a method of mounting a contactor in the present embodiment is applied will be briefly explained.

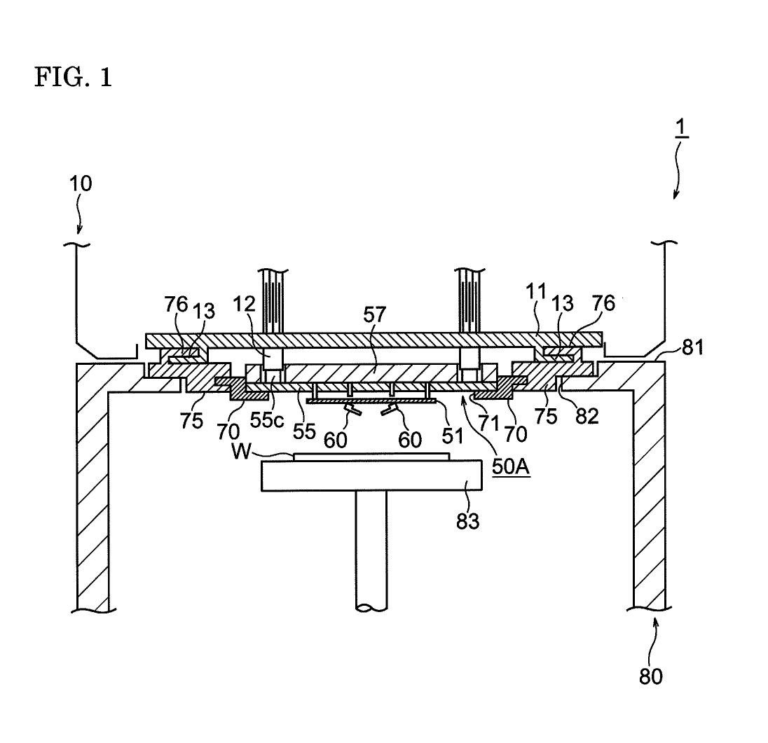

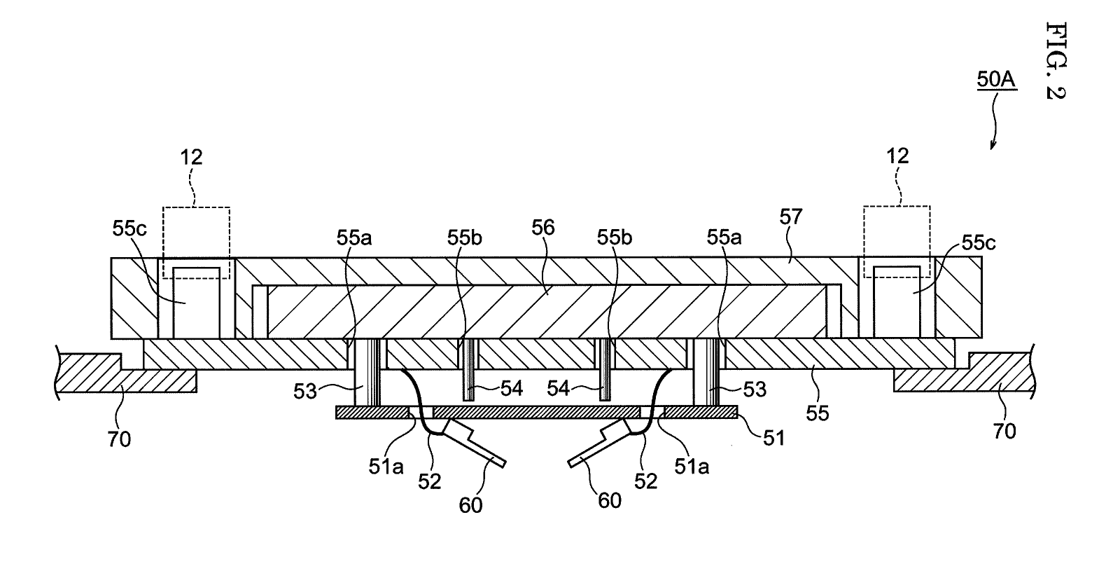

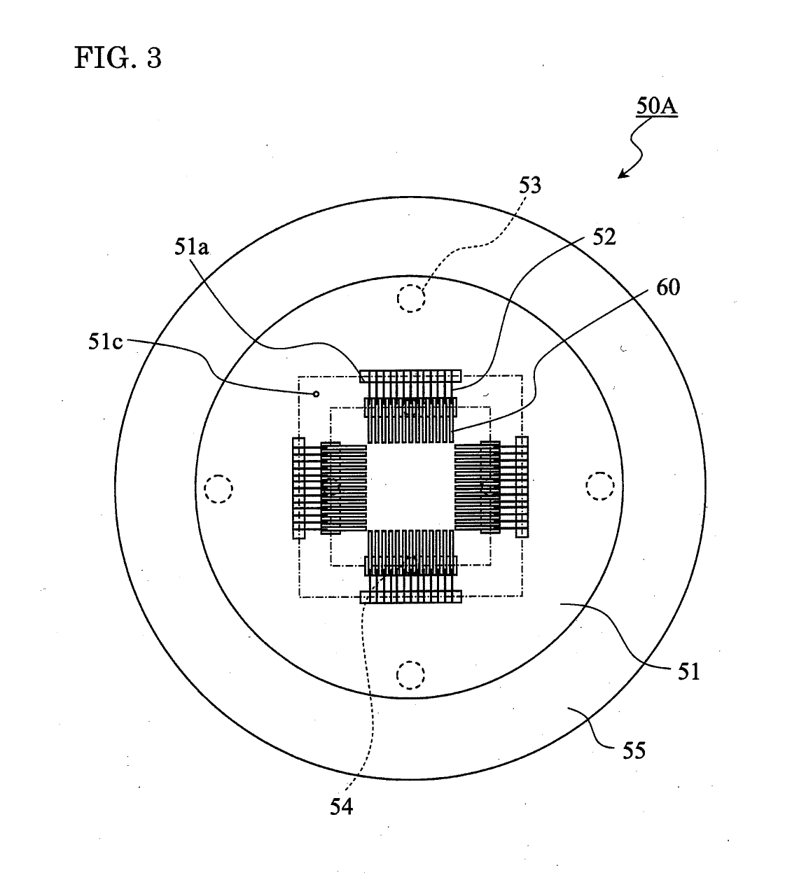

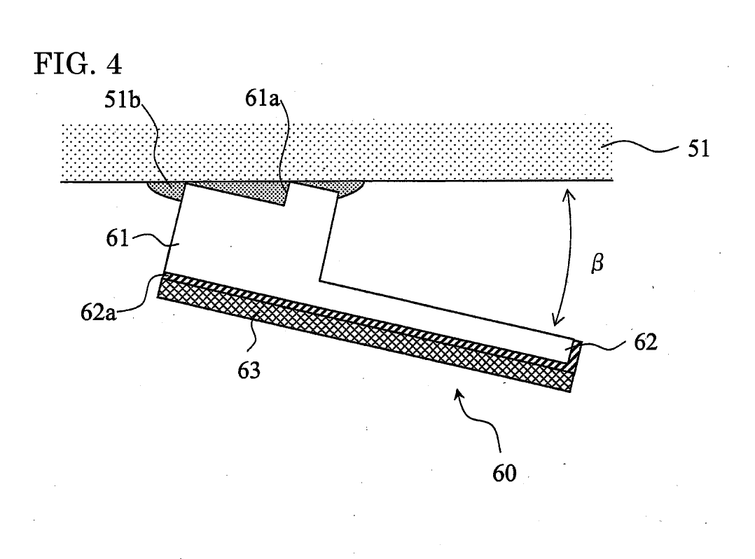

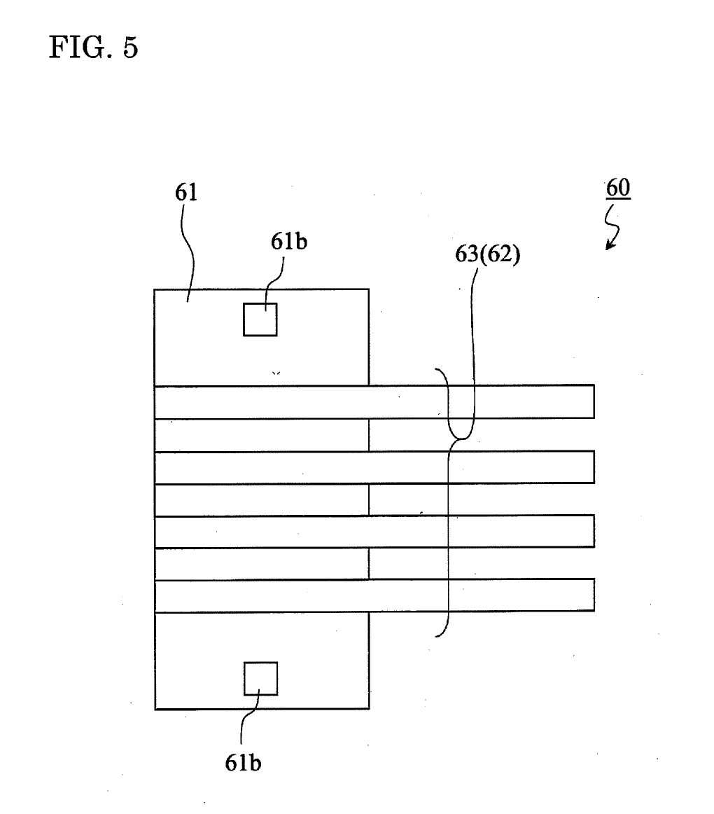

FIG. 1 is a schematic cross-sectional view showing the configuration of an electronic device test system in an embodiment of the present invention, FIG. 2 is a cross-sectional view of a probe card in an embodiment of the present invention, FIG. 3 is a bottom view of a probe card in an embodiment of the present invention, FIG. 4 is a cross-sectional view of a silicon finger contactor in an embodiment of the present invention, and FIG. 5 is a plan view of a silicon finger contactor in an embodiment of the present invention.

The electronic device test system 1 in the present embodiment is a system for testing the electrical characteristics of an IC device built in a semiconductor wafer W made of for example silicon (Si) etc. This electronic device test system 1, as shown in FIG. 1, comprises: a test head 10 electrically connected to a tester (not shown) for testing an IC device via a cable (not shown); a probe card 50 for electrically connecting an IC device on the semiconductor wafer W and the test head 10; and a prober 80 pushing the semiconductor wafer W against the probe card 50.

The probe card 50, as shown in FIG. 1 to FIG. 3, comprises: a large number of silicon finger contactors 60 for electrical contact with input/output terminals of an IC device built in a semiconductor wafer W; a mount base 51 on which the silicon finger contactors are mounted; a circuit board 55 having interconnect patterns (not shown) electrically connected to the silicon finger contactors 60 via bonding wires 52; a base member 56 and stiffener 57 for reinforcing the probe card 50; support columns 53 for supporting the mount base 51; and limiters 54 suppressing deformation of the mount base 51, and is connected via a HIFIX 11 to the test head 10.

Each silicon finger contactor 60, as shown in FIG. 4 and FIG. 5, comprises: a base part 61 fixed to the mount base 51; beam parts 62 with rear end sides provided at the base part 61 and with front end sides sticking out from the base part 61; and conductive layers 63 formed at the surfaces of the beam parts 62.

The base part 61 and beam parts 62 of this silicon finger contactor 60 are made from a silicon substrate using photolithography or other semiconductor production technology. As shown in FIG. 5, a single base part 61 is provided with a plurality of (in this example, four) beam parts 62 in finger shapes (comb shape). By using semiconductor production technology to produce the contactor 60 in this way, it is possible to easily match the pitch between the beam parts 62 with the narrow pitch between the input/output terminals built in the wafer W under test. Note that, in the present invention, the number of the beam parts 62 provided at one base part 61 may be freely set.

As shown in FIG. 4, a step 61a is formed at the rear end of the base part 61. By controlling the ratio of the depth and length of this step 61a, it is possible to freely set the slant angle β of the contactor 60 with respect to the mount base 51. Note that, the smaller this slant angle β, the more preferable.

Further, in the present embodiment, as shown in FIG. 5, the both ends of the top surface of the base part 61 are provided with second marks 61b used when mounting the contactor 60 on the mount base 51. Each second mark 61b is, for example, composed by forming a through hole or metal plating layer at the base part 61.

An insulating layer 62a is formed on the top surfaces of the beam parts 62 for electrically insulating the conductive layer 63 from other parts in the silicon finger contactor 60. This insulating layer 62a is, for example, made of a SiO₂ layer or boron-doped layer.

The conductive layer 63 is formed on the surface of this insulating layer 62a. As the material composing the conductive layer 63, for example, tungsten, palladium, rhodium, platinum, ruthenium, iridium, nickel, or other metal material may be mentioned.

The thus configured silicon finger contactor 60, as shown in FIG. 4, is fixed by an adhesive 51b on the mount base 51 and the front ends face input/output terminals of an IC device built into the wafer W under test. As the binder 51b for fixing the silicon finger contactor 50 to the mount base 51, for example, an ultraviolet light curing type adhesive etc. may be mentioned.

The mount base 51 is a circular shaped board made of a material having somewhat larger efficient thermal expansion than that of the wafer W under test. As the specific material composing the mount base 51, for example, ceramic, kovar, tungsten carbide, stainless invar steel, etc. may be mentioned. Note that, from the viewpoints of ease of processing and inexpensiveness, it is preferable to compose the mount base 51 by a ceramic board. By making the mount base 51 out of a material having a suitable efficient thermal expansion with respect to the wafer W under test, it is possible to reduce the fluctuations in the contact pressures of the contactors 60 caused due to application of temperature and the positional deviation between the front ends of the contactors 60 and the terminals on the wafer W under test.

As shown in FIG. 2 and FIG. 3, rectangular through holes 51a running through the mount base 51 from the front surface to the back surface are formed behind the contactors 60 at the mount base 51. Bonding wires 52 connected to the conductive layers 63 of the contactors 60 are connected via the through holes 51a of the mount base 51 to terminals (not shown) on the circuit board 55. The contactors 60 and the circuit board 55 can be connected by bonding wires 52 given slack so as to allow for the difference in thermal expansion of the mount base 51 and circuit board 55.

Further, in the present embodiment, as shown in FIG. 3, a reference point 51c used when mounting the contactors 60 on the mount base 51 is provided at a predetermined position of the mount base 51. This reference point 51 is, for example, composed of a through hole formed in the mount base 51.

The circuit board 55 is for example a circular board made of a glass epoxy resin. Terminals (not shown) to which the bonding wires 52 are connected are formed at the bottom surface of the circuit board 55. Contactors 55c connecting with connectors 12 at the HIFIX 11 side are provided at the top surface of the circuit board 55. Interconnect patterns (not shown) electrically connecting the terminals of the bottom surface and connectors 55c of the top surface are formed inside the circuit board 55. As the connectors 12, 55c, for example ZIF (Zero Insertion Force) connectors may be used. First through holes 55a for passing the support columns 53 and second through holes 55b for passing the limiters 54 are formed at the circuit board 55 so as to pass through from the front surface to the back surface.

A base member 56 and stiffener 57 are provided on the top surface of the circuit board 55 in order to reinforce the probe card 50. The base member 56 and the stiffener 57 are fixed by for example bolting. Further, the stiffener 57 and the circuit board 55 are fixed at the outer peripheral part of the board 55 by for example bolting. On the other hand, the base member 56 and the circuit board 55 are not directly fixed, so the circuit board 55 is unconstrained at its center part and deformation of the circuit board 55 due to heat expansion of the circuit board 55 is not directly transmitted to the base member 56. As the material composing the base member 56 and stiffener 57, for example, stainless steel, carbon steel, etc. may be mentioned.

The support columns 53 are columnar members for supporting the mount base 51. As shown in FIG. 2, first ends of the support columns 53 are fixed to the mount base 51, while the other ends of the support columns 53 are directly fixed through the first through holes 55a to the base member 56. By directly fixing the support columns 53 to the base member 56, it is possible to prevent the effects of heat expansion of the circuit board 55 from causing fluctuations in the positions of the support columns 53. As the material composing the support columns 53, for example stainless invar steel etc. may be mentioned. As the technique for fixing the support columns 53 to the mount base 51 or base member 56, for example bolting, bonding, etc. may be mentioned.

In the present embodiment, the mount base 51 on which the contactors 60 are mounting and the circuit board 55 on which interconnect patterns electrically connected to the contactors 60 are formed are made from separate boards, and the mount base 51 and the circuit board 55 are noncontact, so even if the circuit board 55 deforms due to heat expansion etc., the deformation will not be transmitted to the mount base 51 mounting the contactors 60, and fluctuation of the contact pressure and positional deviation of the contactors 60 can be reduced.

The limiters 54 are columnar members for preventing deformation of the mount base 51 when pressing the wafer W against the contactors 60. As shown in FIG. 2, first ends of the limiters 54 contact the back surface of the mount base 51 or are positioned near the back surface, while the other ends of the limiters 54 are directly fixed through the second through holes 55b to the base member 56. As the material composing the limiters 54, in the same way as the support column 53, for example, stainless invar steel etc. may be mentioned. As the technique for fixing the limiters 54 to the base member 56, for example bolting, bonding, etc. may be mentioned. The limiters 54 are designed to closely contact the back surface of the mount base 51 and keep the mount base 51 from deforming to the circuit board 55 side when the wafer W is pressed against the probe card 50. Note that, when the mount base 51 has sufficient strength so as not to deform when pressing the wafer W against the contactors 60, the limiters 54 are unnecessary.

The thus configured probe card 50, as shown in FIG. 1, is fixed to a ring-shaped holder 70 in posture that the contactors 60 face to lower side via the center opening 71. The holder 70 is fixed to the ring-shaped adapter 75 in the state holding the probe card 50. Further, the adapter 75 is fixed to the opening 82 formed in the top plate 81 of the prober 80. This adapter 75 is for adapting a different size probe card due to the type of the wafer W under test and the shape of the test head 10 to the opening 82 of the prober 80. The probe card 50 side and the HIFIX 11 side, as shown in FIG. 1, are mechanically coupled by mutual engagement of hooks 13 provided at the bottom surface of the HIFIX 11 and hooks 76 provided at the adapter 75.

The HIFIX 11 is attached to the bottom part of the test head 10. Connectors 12 to which coaxial cables are connected are provided at the bottom surface of this HIFIX 11. By connecting the connectors 12 of the test head 10 side and the connectors 55c provided at the top surface of the circuit board 55 of the probe card 50, the test head 10 and the probe card 50 are electrically connected.

The prober 80 can hold the wafer W by a vacuum chuck and has a conveyor arm 83 enabling the held wafer W to be moved in the XYZ-directions and can convey the wafer W inside the prober 80. Further, at the time of a test, the conveyor arm 83 faces and pushes the wafer W against the probe card 50 facing into the prober 80 via the opening 82. In that state, the tester inputs test signals to the IC device on the wafer W via the test head 10 for receiving the output to test the IC device.

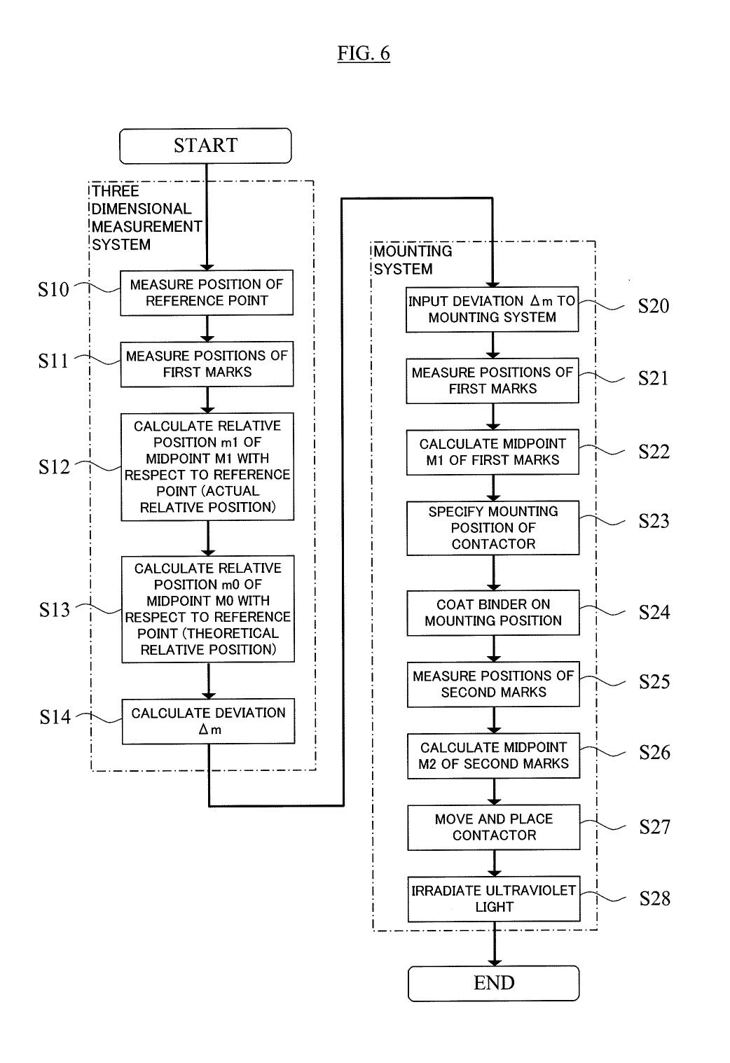

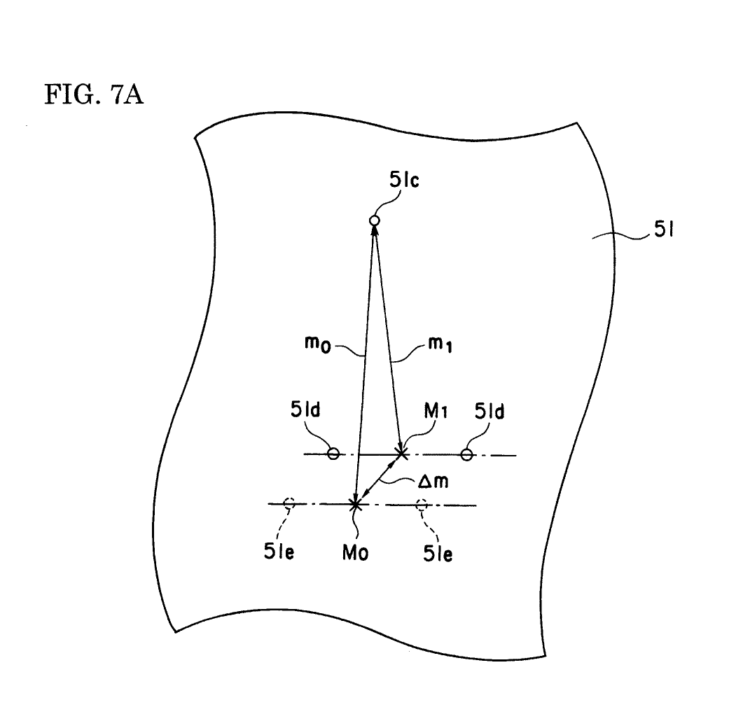

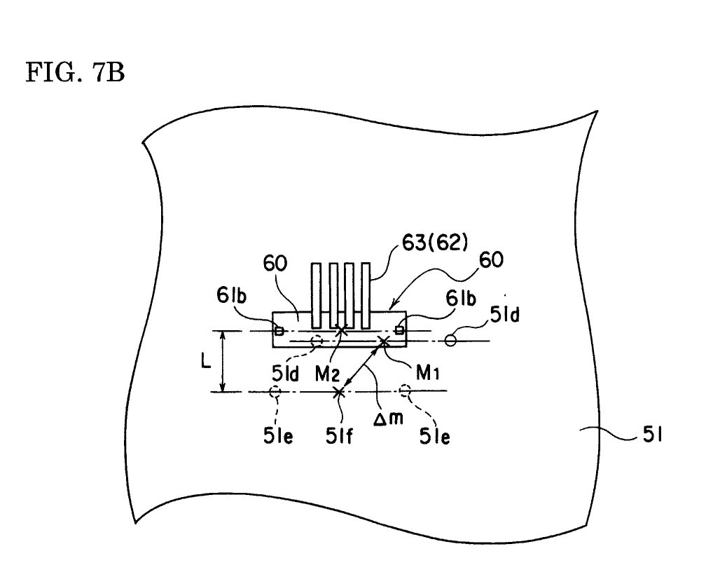

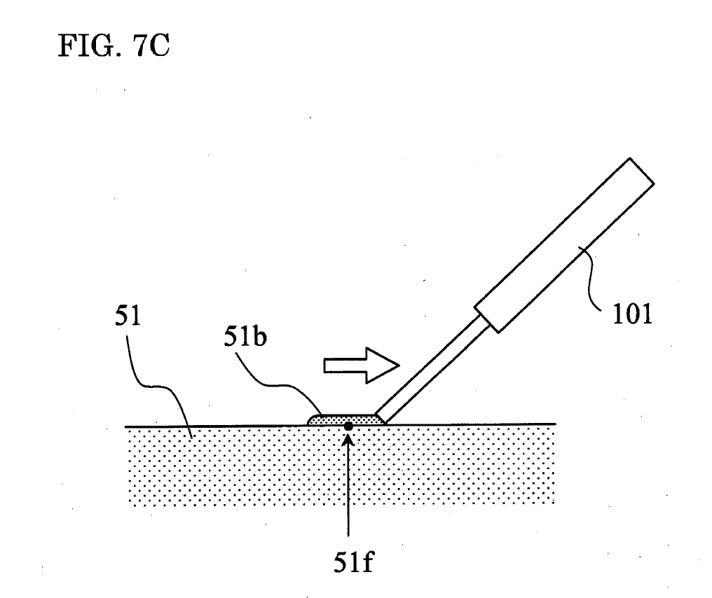

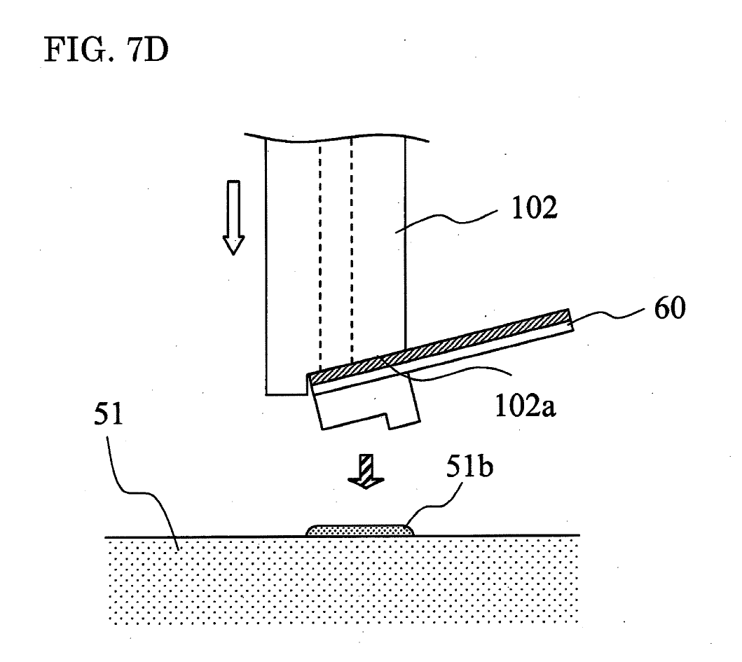

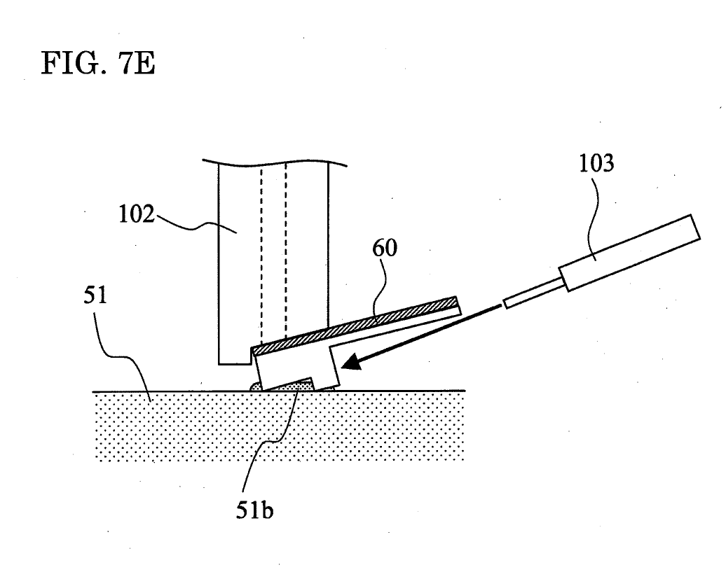

Below, referring to FIG. 6 to FIG. 7E, a method of mounting a contactor on a mount base in the present embodiment will be explained. FIG. 6 is a flow chart showing a method of mounting a contactor in an embodiment of the present invention, while FIG. 7A to FIG. 7E is a view for explaining the steps in FIG. 6.

First, in step S10 of FIG. 6, a three-dimensional measurement system is used to measure the position of the reference point 51c provided in advance on the mount base 51. This reference position 51c is set as the origin (0,0) in the three-dimensional measurement system. As the three-dimensional measurement system used in step S10 and step S11 of FIG. 6, for example, a CNC video measuring device, confocal laser microscope, or other non-contact type can be mentioned.

Next, the three-dimensional measurement system is used to measure the positions of the two first marks 51d actually provided on the mount base 51 in step S11 of FIG. 6 as shown in FIG. 7A. In step S12 of FIG. 6, the relative position m₁ (actual relative position (x₁,y₁)) of the midpoint M₁ of the first marks 51d with respect to the reference point 51c is calculated. Note that, the first marks 51d actually provided on the mount base 51 are, for example, composed of through holes formed in the mount base 51.

Next, the positions of the design first marks 51e in the mount base 51 are read from the CAD data, and the relative position m₀ of the midpoint M₀ of the first marks 51e with respect to the reference point 51c (theoretical relative position (x₀,y₀)) is calculated in step S13 of FIG. 6.

Next, in step S14 of FIG. 6, the relative amount of deviation Δm of the design first marks 51e with respect to the first marks 51d actually provided on the mount base 51 is calculated from the actual relative position m₁ calculated in step S12 and the theoretical relative position m₀ calculated in step S13. Specifically, this amount of deviation Δm is calculated by (Δx,Δy)=(x₁−x₀,y₁−y₀).

In step S20 of FIG. 6, the amount of deviation Δm calculated using the three-dimensional measurement system in the above way is input to the mounting system for mounting the contactor 50 on the mount base 51. Next, the mounting system uses image processing technology etc. to measure the positions of the two first marks 51d actually formed on the mount base 51 in step S21 of FIG. 6, and the position (Xₘ,Yₘ) of the midpoint M₁ of these two first marks 51d is calculated in step S22 as shown in FIG. 7B.

Next, in step S23 of FIG. 6, as shown in FIG. 7B, the position 51f at which the silicon finger contactor 60 should be mounted on the mount base 51 (mounting position) is specified on the basis of the midpoint M₁ calculated in step S22 and the amount of deviation Δm input in step S20. Specifically, the mounting position is calculated by (Xₐ,Yₐ)=(Xₘ−Δx,Yₘ−Δy). That is, in the present embodiment, the position 51f at which the contactor 60 should be mounted on the mount base 51 matches the midpoint M₀ of the design first marks 51e in the mount base 51, and it is possible to cancel out the processing error caused when forming the first marks 51d on the mount base 51.

Next, as shown in FIG. 7C, the coating unit 101 of the mounting system coats an adhesive 51b on the mounting position 51f of the mount base 51 in step S24 of FIG. 6. This coating unit 101, while not particularly shown, for example, has a syringe in which an ultraviolet light curing adhesive is filled and can apply a predetermined amount of adhesive on the mount base

Next, the mounting system uses a pickup unit 102 to hold a silicon finger contactor 60 by suction and, in that state, uses image processing technology etc. to measure the positions of the two second marks 61b actually provided at the both ends of the base part 61 of the contactor 60 in step S25 of FIG. 6, and the position of the midpoint M₂ of these two second marks 61b is calculated in step S26 as shown in FIG. 7B.

Next, in step S27 of FIG. 6, the mounting system moves the silicon finger contactor 60 by the pickup unit 102 as shown in FIG. 7D and places the silicon finger contactor 60 on the mount base 51 in the state where the midpoint M₂ of the second marks 61b is separated from the mounting position 51f by exactly a predetermined distance L as shown in FIG. 7B. Note that, as shown in FIG. 7D, the front end of the pickup unit 102 is provided with a pickup surface 102a having substantially the same angle as the mounting angle β of the contactor 60 with respect to the mount base 51

Next the illuminating unit 103 of the mounting system illuminates the adhesive 51b with ultraviolet light to cure the adhesive 51b and fix the contactor 60 to the mount base 51 in step S28 of FIG. 6 as shown in FIG. 7E.

As explained above, in the present embodiment, the reference point 51c is provided on the mount base 51 on which the contactor 60 mounted, the relative position of the actual first marks 51d (actual relative position m₁) and the relative position of the design first marks 51d (theoretical relative position m₀) with respect to the reference point 51c are calculated, the relative amount of deviation Δm of the actual relative position m₁ with respect to the theoretical relative position m₀ is calculated, and the amount of deviation Δm is considered when specifying the mounting position of the contactor 60 on the mount base 51. For this reason, the processing error caused when forming the first marks 51d on the mount base 51 can be cancelled out, so it is possible to precisely mount the silicon finger contactor 60 on the mount base 51.

Note that, the above explained embodiment was described for facilitating understanding of the present invention and was not described for limiting the present invention. Therefore, the elements disclosed in the above embodiment include all design changes and equivalents falling under the technical scope of the present invention.

For example, in the above embodiment, the explanation was given with reference to use of a silicon finger contactor 60 as a contactor mounted on the board, but the present invention is not particularly limited so long as the contactor requires positioning when being mounted on a board.

Further, in the above embodiment, the explanation was given with reference to use of a mount base 51 as the board on which the contactors are mounted, but the present invention is not particularly limited to this. For example, when directly mounting contactors on a circuit board, it is possible to provide the reference point and first marks on the circuit board.

1. A method of mounting a contactor on a board, the contactor for electrical contact with input/output terminal of a device under test at the time of testing the device under test, the method of mounting a contactor comprising:
recognizing a position of a reference point provided on the board;
recognizing a first position of a first mark provided on the board for showing a position for mounting the contactor and calculating an actual relative position of the first mark with respect to the reference point;
calculating a theoretical relative position in design of the first mark with respect to the reference point;
calculating a relative amount of deviation of the actual relative position with respect to the theoretical relative position on the basis of the actual relative position and the theoretical relative position;
recognizing a second position of the first mark;
specifying a mounting position of the contactor on the board on the basis of the amount of deviation and the second position of the first mark; and
mounting the contactor at the mounting position.

2. The method of mounting a contactor as set forth in claim 1, wherein the specifying the mounting position comprises: calculating the theoretical position in design of the first mark on the basis of the second position of the first mark and the amount of deviation; and specifying the theoretical position as the mounting position of the contactor on the board.

3. The method of mounting a contactor as set forth in claim 1, wherein
the method further comprising recognizing a position of a second mark provided on the contactor for recognizing the position of the contactor, wherein
mounting the contactor comprises mounting the contactor on the board so that the second mark is positioned at the mounting position or the second mark is positioned a predetermined distance away from the mounting position.

4. The method of mounting a contactor as set forth in claim 3, wherein
the position of the reference point and the first position of the first mark are recognized by a first measurement system, and
the second position of the first mark and the position of the second mark are recognized by a second measurement system different from the first measurement system.

5. The method of mounting a contactor as set forth in claim 1, wherein, when mounting a plurality of the contactors on the same board, the position of the same reference point is recognized.

6. The method of mounting a contactor as set forth in claim 1, further comprising a coating step of coating an adhesive on the mounting position.

7. The method of mounting a contactor as set forth in claim 1, wherein
the contactor has
a base part fixed to the board,
beam parts with rear end sides provided at the base part and front end sides sticking out from the base part, and
conductive parts formed on surfaces of the beam parts and electrically connecting with input/output terminals of the device under test,
one the base part is provided with a plurality of the beam parts, and
the second mark is provided at the base part.
